(19) United States
(12) Patent Application Publication
(10) Pub. No.: US 2005/0163208 A1
(43) Pub. Date: Jul. 28, 2005

(54) Equalized signal path with predictive subtraction signal and method therefor

(75) Inventor: Ronald Duane McCallister, Scottsdale, AZ (US)

Correspondence Address: Lowell W. Gresham;Meschkow & Gresham, P.L.C., Suite 409, 5727 North Seventh Street, Phoenix, AZ, 85014, US

(73) Assignee: CrestCom, Inc., Scottsdale, AZ (US)

(21) Appl. No.: 10/971,628

(22) Filed: Oct. 22, 2004

Related U.S. Application Data
(63) Continuation-in-part of application No. 10/871,670, filed on Jun. 17, 2004.
Application No. 10/871,670 is a continuation-in-part of application No. 10/766,768, filed on Jan. 27, 2004.

(51) Int. Cl. H03K 5/159

(52) U.S. Cl. 375/232; 375/297

(57) ABSTRACT

A digital communication transmitter serves as a signal path (10) which uses an adaptive equalizer (18) in a predistortion role. The adaptive equalizer (18) pre-distorts a complex digital communication signal (12) that need not exhibit any distortion. Subsequent analog distortion-introducing segments (24, 30, 36, 42) then distort a predistorted signal (22) output from the adaptive equalizer (18). An error signal (46) is formed from a reference signal (52) and a return signal (54). The equalizer (18) implements an adaptation algorithm that adjusts filter (68) coefficients to minimize correlation between one of the reference and return signals (52, 54) and the error signal (46). The equalizer (18) generates four sets of coefficients for four different filters. Consequently, the equalizer (18) exhibits four degrees of freedom in introducing predistortion into a complex signal to counter the distortion subsequently introduced in the signal path (10) by the distortion-introducing segments (24, 30, 36, 42).

### RELATED INVENTIONS

This patent is a continuation-in-part of “Equalized Signal Path with Predictive Subtraction Signal and Method Therefor,” Ser. No. 10/871,670, filed 17 Jun. 2004, which is a continuation-in-part of “Predistortion Circuit and Method for Compensating Linear Distortion in a Digital RF Communications Transmitter,” Ser. No. 10/766,768, filed 27 Jan. 2004, both by the inventor of the present patent, and both incorporated herein by reference.

This patent is related to “A Distortion-Managed Digital RF Communications Transmitter and Method Therefor,” (Ser. No. 10/766,801, filed 27 Jan. 2004); to “Predistortion Circuit and Method for Compensating Nonlinear Distortion in a Digital RF Communications Transmitter” (Ser. No. 10/766,779, filed 27 Jan. 2004); and, to “Predistortion Circuit and Method for Compensating A/D and Other Distortion in a Digital RF Communications Transmitter” (Ser. No. 10/840,735, filed 6 May 2004), each of which was invented by the inventor of this patent and each of which is incorporated herein by reference.

### TECHNICAL FIELD OF THE INVENTION

The present invention relates generally to adaptive equalizers and more specifically to the use of an adaptive equalizer to equalize a signal path.

### BACKGROUND OF THE INVENTION

Adaptive equalizers are essentially filters whose filtering characteristics change over time to match or counter some system characteristic. An adaptation algorithm is implemented to specify how the filtering characteristics change. A variety of adaptation algorithms, including the Least-Mean-Square (LMS), steepest-descent, recursive least-squares (RLS) and others, has been developed for adaptive equalizers. Of the variety of algorithms, the LMS algorithm, which is one form of a steepest-descent algorithm, is particularly popular due to its excellent performance, robust convergence characteristics, and simplicity of implementation.

Adaptive equalizers have been successfully used in communication systems, control systems, radar systems, and other systems, typically where too little information is available about an incoming signal. A representative application is in the equalization of a communication channel. In this application, the adaptive equalizer is located in a communication receiver to compensate for an unknown distortion introduced in the transmission medium and/or to track changes in the distortion. Other conventional applications for adaptive equalizers include system identification, noise cancellation, echo cancellation, beamforming, and linear predictive coding. These applications have one feature in common. The unknown, or imperfectly known, distortion or other signal characteristic to be equalized or filtered is introduced into a signal path prior to the equalizer, then the equalizer adapts to accommodate the distortion.

But conventional adaptive equalizer techniques can achieve disappointing results if an adaptive equalizer is used in a predistortion role. In a predistortion role, an adaptive equalizer imparts a distortion to an ideal signal that is received at the equalizer's input. The adaptive equalizer's incoming signal may have received prior processing that affected its spectral characteristics, but is nevertheless considered an undistorted signal from the perspective of the adaptive equalizer. Desirably, the predistortion imparted by the adaptive equalizer is of a particular configuration so that when the predistorted signal is then passed through a distortion-introducing segment of the signal path, the resulting path-output signal has desired characteristics. In this application, a “pure” distorted signal, i.e., one that has not been altered by equalization, is unavailable, so the conventional LMS adaptation algorithm is unrealizable. Consequently, a need exists for an LMS-like adaptive equalizer that relies upon signals available when the adaptive equalizer is used in a predistortion role.

In addition, conventional adaptive equalizer techniques can be inadequate in some applications when a complex signal is to be filtered. A complex signal has two signal components which are independent of each other but are otherwise in a quadrature relationship. The two signal components are typically referred to as real and imaginary components or in-phase and quadrature components. The conventional LMS adaptation algorithm, when adjusted to accommodate a complex signal, generates a complex weighting vector that acts upon a complex distorted input signal through a complex filter. While this complex weighting vector is desirable in some respects, it results in only two degrees of freedom (one real and one imaginary) with respect to countering the distortion of the incoming complex signal.

When an equalizer is conventionally located in a signal path after a significant source of distortion, such as the transmission medium discussed above, a two-degree-of-freedom adaptive equalizer is desirable. In this conventional application substantially the same distortion is imparted to each component of the complex signal. But in other applications, a signal path may suffer from types of distortion, such as significant quadrature imbalance, that cannot be effectively countered with an adaptive equalizer having only two degrees of freedom. Significant quadrature imbalance may result, for example, from using separate analog legs of the signal path to process the real and imaginary components of the complex signal. Accordingly, a need exists for a complex adaptive equalizer that has more than two degrees of freedom so as to be able to counter significant quadrature imbalance.

### SUMMARY OF THE INVENTION

It is an advantage of at least one embodiment of the present invention that an improved equalized signal path having a predictive subtraction signal and a corresponding method are provided.

Another advantage of at least one embodiment of the present invention is that one of the signals used in forming an error signal for an adaptation algorithm operates as a predictive variable which the adaptation algorithm correlates with the error signal.

Another advantage of at least one embodiment of the present invention is that a complex adaptive equalizer having four degrees of freedom is provided.

These and other advantages are realized in one form by an equalized signal path into which a path-input signal flows and from which a path-output signal flows. The equalized signal path includes a subtraction circuit configured to generate an error signal by combining first and second subtraction signals. The first subtraction signal is a reference signal and the second subtraction signal is derived from the path-output signal. A coefficient generator is adapted to track correlation between the error signal and one of the subtraction signals. A multiplier circuit is coupled to the coefficient generator and is configured to scale the path-input signal in response to the correlation tracked by the coefficient generator.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a block diagram of a digital communication transmitter that provides one example of a signal path in accordance with the teaching of the present invention;

FIG. 2 shows a block diagram of an exemplary equalizer portion of the signal path depicted in FIG. 1;

FIG. 3 shows a block diagram of an exemplary coefficient generator section of the equalizer depicted in FIG. 2;

FIG. 4 shows a block diagram of an exemplary filter from the equalizer depicted in FIG. 2;

FIG. 5 shows a block diagram of an alternate embodiment of the equalizer portion of the signal path depicted in FIG. 1; and

FIG. 6 shows a block diagram of a tap slice of an adaptation engine depicted in FIG. 5.

### DETAILED DESCRIPTION OF THE PREFERRED EMBODIMENTS

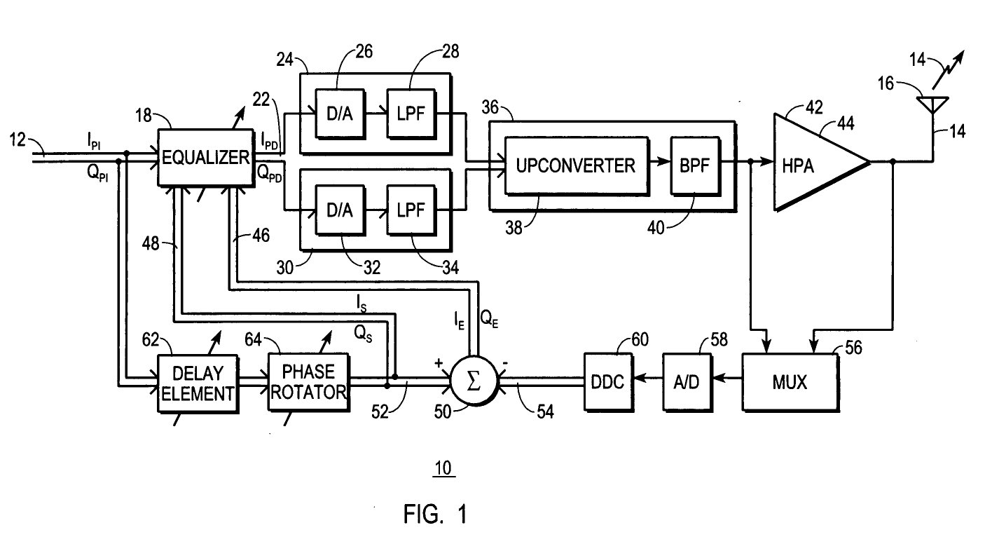

FIG. 1 shows a block diagram of a digital communication transmitter 10 that provides one example of a signal path in accordance with the teaching of the present invention. Henceforth, transmitter 10 will also be referred to as signal path 10. Signal path 10 is adapted to receive a path-input signal 12 and to generate a path-output signal 14. In the exemplary embodiment where signal path 10 is a digital communication transmitter, path-input signal 12 is a complex digital baseband communication signal. As such, path-input signal 12 has an in-phase component I_{PI} and a quadrature component Q_{PI}. The baseband communication signal may have been encrypted, forward-error-correction (FEC) encoded, framed, digitally modulated, combined with other digitally modulated communication signals, pulse shaped, peak limited, and the like, prior to being applied to signal path 10 as path-input signal 12. In this exemplary embodiment, path-output signal 14 is an analog radio-frequency (RF) communication signal which is broadcast from an antenna 16. But those skilled in the art will appreciate that the broad aspects of the present invention are not strictly limited to this digital RF communication example.

Path-input signal 12 is applied to an adaptive equalizer 18. Signal path 10 places equalizer 18 in a predistortion role. In other words, path-input signal 12 is considered to be substantially undistorted for purposes of the present invention. Equalizer 18 is not included for purposes of countering or matching any distortion that might have been present in path-input signal 12. Rather, equalizer 18 generates a predistorted signal 22, which is a complex signal having an in-phase component I_{PD} and a quadrature component Q_{PD} in the preferred embodiment, that drives one or more distortion-introducing segments.

In the digital RF communication example, in-phase component I_{PD} of predistorted signal 22 drives an analog in-phase distortion-introducing segment 24 which includes a digital-to-analog (D/A) converter 26 followed by a low-pass filter 28. Quadrature component Q_{PD} of predistorted signal 22 drives an analog in-phase distortion-introducing segment 30 which includes a digital-to-analog (D/A) converter 32 followed by a low-pass filter 34. Distortion-introducing segments 24 and 30 collectively drive an analog combined distortion-introducing segment 36 which includes an upconverter 38 followed by a band-pass filter (BPF) 40. Upconverter 38 is preferably configured to implement a direct quadrature upconversion in this example. And, distortion-introducing segment 36 drives an analog distortion-introducing segment 42 which includes a high-power amplifier (HPA) 44. High-power amplifier 44 generates the RF communication signal that serves as path-output signal 14.

Distortion-introducing segments 24, 30, 36, and 42 include a variety of sources for potential distortions that may be introduced into predistorted signal 22. These sources result from the inaccuracies characteristic of analog processing. For example, the two different D/A's 26 and 32 may not exhibit precisely the same gain and may introduce slightly different amounts of delay. Such differences in gain and delay can lead to linear distortion. Moreover, so long as the different legs of the complex signal are processed separately in different analog components, the components are likely to apply slightly different frequency responses so that linear distortion, particularly in the form of quadrature imbalance, is worsened by the introduction of frequency-dependent gain and phase imbalances. And, the frequency-dependent gain and phase imbalances worsen as the bandwidth of the communication signal widens. LPF's 28 and 34 can be the source of additional linear distortion by applying slightly different gains and phase shifts in addition to slightly different frequency-dependent characteristics. Additional linear distortion in the form of gain and phase imbalance may be introduced at upconverter 38. BPF 40 will also introduce additional phase delay into predistorted signal 22, and more quadrature imbalance will result to the extent that BPF 40 is not precisely centered in the desired frequency band. HPA 44 is likely to be the source of yet another set of linear distortions in addition to nonlinear distortion.

In this RF communication example, equalizer 18 desirably implements an adaptation algorithm, discussed below, to introduce a pre-distortion that counters the linear distortions introduced up to and through HPA 44. Thus, as far as possible path-output signal 14 will be free of distortion. The reduction of linear distortion is desirable in its own right because it leads to improved performance in a communication system that includes digital communication transmitter 10 and a receiver (not shown). But it is also desirable because it improves the ability of nonlinear predistortion circuits (not shown) in a transmitter to characterize and counter the nonlinear distortion introduced by HPA 44. The reduction of nonlinear distortion is desirable because it reduces spectral regrowth and/or allows the use of a less expensive HPA 44.

The adaptation algorithm implemented by equalizer 18 is driven by a complex error signal 46 having an in-phase component I_{E} and a quadrature component Q_{E}. It is also driven by a subtraction signal 48 having an in-phase component I_{S} and a quadrature component Q_{S}. A complex subtraction circuit 50 generates error signal 46 by combining a complex reference signal 52 with a complex return signal 54. Reference signal 52 and return signal 54 are each subtraction signals for subtraction circuit 50, and either reference signal 52 or return signal 54 may serve as the subtraction signal which drives the adaptation algorithm of equalizer 18. While either subtraction signal may drive the adaptation algorithm of equalizer 18, FIG. 1 depicts only reference signal 52 in this role for convenience. Moreover, it matters little which of subtraction signals 52 and 54 is in the role of subtrahend or in the role minuend with respect to subtraction circuit 50—so long as polarities are arranged properly throughout signal path 10.

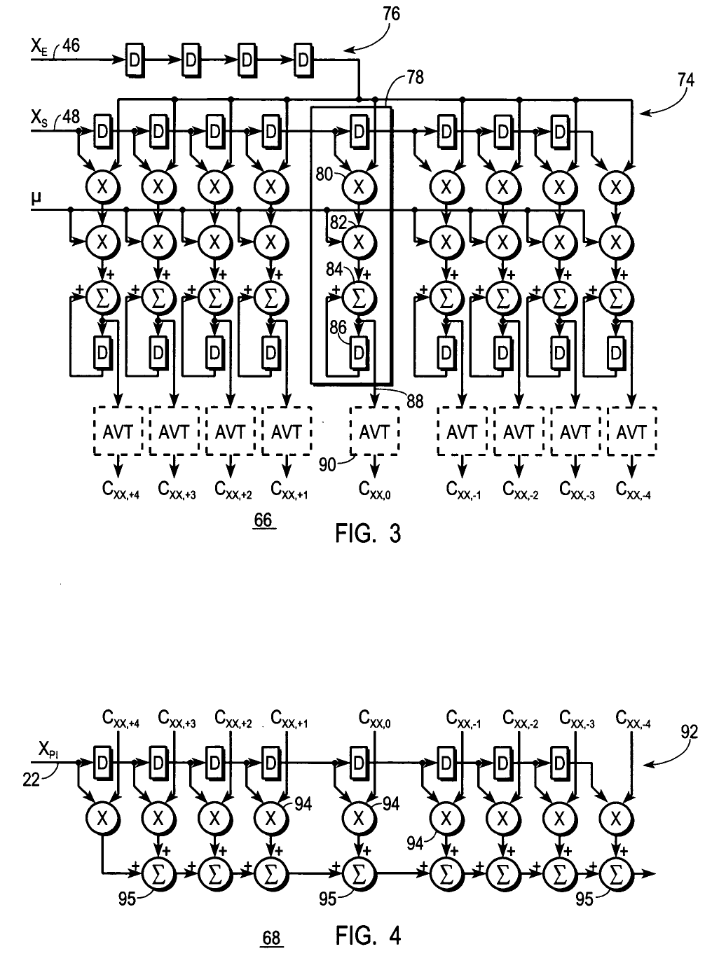

While either subtraction signal may drive the adaptation algorithm of equalizer 18, the presently preferred embodiment of signal path 10, uses reference signal 52 in this role because return signal 54 in this presently preferred embodiment includes a small amount of quantization noise introduced by an analog-to-digital (A/D) converter 58. This quantization noise component is not present in reference signal 52. Unlike return signal 54, reference signal 52 is derived from path-input signal 12 without performing analog signal processing. Moreover, this quantization noise would be present in both subtraction signal 48 and error signal 46 if return signal 54 were selected as subtraction signal 48. As discussed below in connection with FIG. 3, the adaptation algorithm of equalizer 18 in this presently preferred embodiment can multiply subtraction signal 48 and error signal 46, causing the quantization noise component to become squared. If the quantization noise were to become squared, it would not have a zero mean and might possibly introduce bias into the adaptation algorithm of equalizer 18.

Return signal 54 is derived from path-output signal 14. In particular, an analog multiplexer (MUX) 56 has inputs coupled to the outputs of BPF 40 and HPA 44 and an output coupled to an input of A/D 58. An output of A/D 58 couples to a digital-downconversion (DDC) section 60, and DDC 60 generates return signal 54. A/D 58 need not provide a high degree of digital resolution, but desirably provides a highly linear output. A/D compensation circuits (not shown) may be included as needed to improve linearity. An example of suitable A/D compensation circuits and an accompanying process are disclosed in the above-referenced related patent entitled “Predistortion Circuit and Method for Compensating A/D and Other Distortion in a Digital RF Communications Transmitter.” DDC 60 desirably implements a complex-digital-subharmonic-sampling downconverter, an example of which is disclosed in more detail in the above-referenced related patents.

Reference signal 52 is derived from path-input signal 12 using digital processing. In particular, path-input signal 12, or a signal derived therefrom, drives a delay element 62. An output of delay element 62 drives a phase rotator 64, and an output of phase rotator 64 generates reference signal 52. Unlike distortion-introducing segments 24, 30, 36, and 42, delay element 62 and phase rotator 64 do not impart significant distortion to path-input signal 12 due to the use of digital processing. Likewise no quantization error is added in reference signal 52, as occurs in return signal 54 through the operation of A/D 58.

Delay element 62 and phase rotator 64 are each desirably programmable circuits which insert specified amounts of delay and phase rotation, respectively, to improve the efficiency of equalizer 18. Desirably, delay element 62 and phase rotator 64 are each programmed so that subtraction signals 52 and 54 are in temporal and phase alignment with each other. In other words, delay element 62 is programmed to compensate for delay introduced by distortion-introducing segments 24, 30, 36, and when appropriate, 42 as well as for return path components 56, 58, and 60. And, phase rotator 64 is programmed to compensate for phase rotation introduced primarily by BPF 40. In general the programming may be accomplished by monitoring an RMS error estimator (not shown) driven by error signal 46 while using an algorithm that determines the programming for delay element 62 and phase rotator 64 which minimizes the RMS level of error signal 46. This process is preferably performed while equalizer 18 applies substantially no influence on the digital signal flowing through it. Examples of suitable programmable circuits for delay element 62 and phase rotator 64 and for processes suitable for determining the programming therefor are disclosed in more detail in the above-referenced related patents.

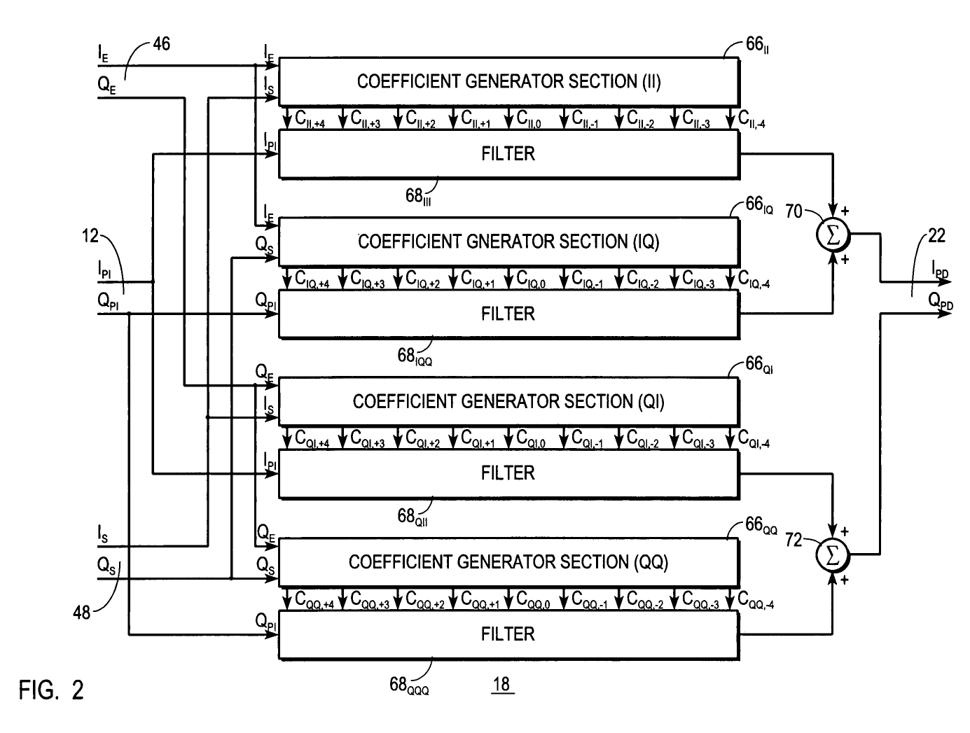

FIG. 2 shows a block diagram of an exemplary equalizer 18 which may be used in signal path 10 (FIG. 1). Equalizer 18 includes four coefficient generator sections 66_{II}, 66_{IQ}, 66_{QI}, and 66_{QQ} and four filter sections 68_{III}, 68_{IQQ}, 68_{QII}, and 68_{QQQ}. Coefficient generator section 66_{II} receives the in-phase component I_{E} of error signal 46 and the in-phase component I_{S} of subtraction signal 48, and coefficient generator section 66_{II} generates coefficients C_{II,-4} through C_{II,+4} in response to the correlation between the I_{E} and I_{S} components. Filter 68_{III} receives the in-phase component I_{PI} of path-input signal 12 and scales the I_{PI} component at different points in time in response to coefficients C_{II,-4} through C_{II,+4}. While FIG. 2 depicts nine of coefficients C_{II,-4} through C_{II,+4} in connection with coefficient generator sections 68 and filters 68, this number of coefficients is exemplary only and not a critical factor.

Coefficient generator section 66_{IQ} receives the in-phase component I_{E} of error signal 46 and the quadrature component Q_{S} of subtraction signal 48, and coefficient generator section 66_{IQ} generates coefficients C_{IQ,-4} through C_{IQ,+4} in response to the correlation between the I_{E} and Q_{S} components. Filter 68_{IQQ} receives the quadrature component Q_{PI} of path-input signal 12 and scales the Q_{PI} component at different points in time in response to coefficients C_{IQ,-4} through C_{IQ,+4}.

Likewise, coefficient generator section 66_{QI} receives the quadrature component Q_{E} of error signal 46 and the in-phase component I_{S} of subtraction signal 48, and coefficient generator section 66_{QI} generates coefficients C_{QI,-4} through C_{QI,+4} in response to the correlation between the Q_{E} and I_{S} components. Filter 68_{QII} receives the in-phase component I_{PI} of path-input signal 12 and scales the I_{PI} component at different points in time in response to coefficients C_{QI,-4} through C_{QI,+4}.

And, coefficient generator section 66_{QQ} receives the quadrature component Q_{E} of error signal 46 and the quadrature component Q_{S} of subtraction signal 48, and coefficient generator section 66_{QQ} generates coefficients C_{QQ,-4} through C_{QQ,+4} in response to the correlation between the Q_{E} and Q_{S} components. Filter 68_{QQQ} receives the quadrature component Q_{PI} of path-input signal 12 and scales the Q_{PI} component at different points in time in response to coefficients C_{QQ,-4} through C_{QQ,+4}.

Outputs of filters 68_{III} and 68_{IQQ} are added together in a combination circuit 70 to generate the in-phase component I_{PD} of predistorted signal 22. Likewise, outputs of filters 68_{QII} and 68_{QQQ} are added together in a combination circuit 72 to generate the quadrature component Q_{PD} of predistorted signal 22.

Adaptive equalizer 18 thus provides four degrees of freedom. Nothing forces the influence of the in-phase input signal on the in-phase output signal to equal the influence of the quadrature input signal on the quadrature output signal. Likewise, nothing forces the influence of the in-phase input signal on quadrature output signal to equal the influence of the quadrature input signal on the in-phase output signal. Consequently, adaptive equalizer 18 has full freedom to adjust coefficients as needed to remedy quadrature imbalance.

FIG. 3 shows a block diagram of an exemplary coefficient generator section 66 of equalizer 18 (FIG. 2). Coefficient generator section 66 may be used for any of the four coefficient generator sections 66_{II}, 66_{IQ}, 66_{QI}, and 66_{QQ} depicted in FIG. 2. Coefficient generator section 66 receives its subtraction signal 48 at a tapped-delay line 74. Tapped-delay 74 progressively delays subtraction signal 48 through a number of taps. Nine taps are illustrated in FIG. 3 only to maintain consistency with the number of coefficients depicted in FIG. 2.

Coefficient generator section 66 receives its error signal 46 at a delay line 76 which delays the error signal to the middle of tapped-delay line 74. Hence, temporal alignment of error signal 46 with subtraction signal 48 occurs most precisely at a center tap slice 78, which generates a center coefficient C_{XX,0}. Subtraction signal 46 progressively follows error signal 48 for the tap slices that generate coefficients C_{XX,-1} through C_{XX,-4}, and progressively leads error signal 48 for the tap slices that generate coefficients C_{XX,+1} through C_{XX,+4}. Those skilled in the art will appreciate that the amount of delay, if any, imposed in delay line 76 may vary depending upon the application.

FIG. 3 blocks only tap slice 78, but all tap slices are configured identically in the preferred embodiment. Thus, tap slice 78 and the other tap slices each include a multiplier 80 which received the delayed error signal output from delay line 76 and the corresponding delayed subtraction signal from tapped-delay line 74. The output from multiplier 80 provides a correlated signal that tracks the correlation between error signal 46 and the subtraction signal 48 at the relative timing therebetween set up for the tap position. This correlated signal is routed to a multiplier 82 which multiplies the correlated signal by a programmable constant μ supplied by a controller (not shown). An output of multiplier 82 drives an integrator which includes an adder 84 and a one-cycle delay element 86. In particular, a correlation step signal output from multiplier 82 drives a first input of adder 84, an output of adder 84 generates a coefficient signal 88 that drives an input of delay element 86, and an output of delay element 86 drives a second input of adder 84.

Delay element 86 acts as a coefficient register which retains the previous coefficient output for the tap slice. That coefficient is updated in a current cycle with a small fraction of the correlation existing between error signal 46 and subtraction signal 48, at the temporal alignment set up for the tap. The precise size of the small fraction is dictated by the programmable constant μ. Smaller values of μ cause smaller changes in coefficient value from cycle to cycle and slower convergence. Convergence occurs when correlation averages equal the values that minimize rms error energy. Moreover, the correlation of interest is between error signal 46 and a predictive variable obtained from one of the subtraction signals 52 or 54 (FIG. 1) used to form error signal 46.

To begin the adaptation algorithm, coefficients for all coefficient registers 86 in coefficient generator sections 66_{IQ} and 66_{QI} are desirably initialized to low magnitude values, preferably zero. And, except for center tap slice 78 in coefficient generator sections 66_{II} and 66_{QQ}, all coefficient registers 86 are initialized to low magnitude values. But coefficient registers 86 at center tap slice 78 in coefficient generator sections 66_{II} and 66_{QQ} are initialized to relatively high magnitude values, such as in the range of 0.6 to 0.95. This arrangement helps maintain the full temporal authority of equalizer 18.

In one embodiment, an optional additional variable tracking (AVT) section 90 is added to process coefficients C_{XX,-4} through C_{XX,+4} and cause coefficients C_{XX,-4} through C_{XX,+4} to further vary in response to an additional variable. The above-referenced related patents discuss in detail one such additional variable tracking section 90 that compensates for variation in coefficients with respect to a signal responsive to the power of path-input signal 12 (FIG. 1), compensating for heat-induced memory effects in HPA 44. But other applications may track other variables, or may omit additional variable tracking section 90 altogether.

Thus, when coefficient generator section 66 is operated with the other coefficient generator sections 66 shown in FIG. 2, four different coefficients are generated in association with the various taps of tapped delay line 74. The four different coefficients result from tracking correlation for four different combinations of the in-phase and quadrature components of the error and subtraction signals 46 and 48.

Those skilled in the art will realize that some reduction in components may be gained by combining the functions of coefficient generator sections 66. For example, pairs of coefficient generator sections 66 may be configured to use a common tapped delay line 74 and delay line 76. In addition, variants of conventional LMS adaptive equalizers may also be applied in the present invention to reduce implementation complexity. For example, a sign-data adaptation algorithm may be implemented by using only the sign or polarity of error signal 46 in coefficient generator sections 66, a sign-error adaptation algorithm may be accommodated by using only the sign of subtraction signal 48 in coefficient generator sections 66, and a sign-sign adaptation algorithm may be accommodated by using only the signs of both error signal 46 and subtraction signal 48.

FIG. 4 shows a block diagram of an exemplary filter 68 from equalizer 18 (FIG. 2). Filter 68 may be used for any of the four filters 68_{III}, 68_{IQQ}, 68_{QII}, and 66_{QQQ} depicted in FIG. 2. Filter 68 follows a finite impulse response (FIR) structure in the preferred embodiment and receives its path-input signal 12 at a tapped-delay line 92. Tapped outputs from tapped-delay line 92 couple to first inputs of multipliers 94, and second inputs of multipliers 94 receive coefficients C_{XX,-4} through C_{XX,+4} from the corresponding coefficient generator section 66 (FIGS. 2-3). Nine taps are illustrated in FIG. 4 only to maintain consistency with the number of coefficients depicted in FIGS. 2 and 3. Filter 68 scales its path-input signal 12 at different points in time in response to coefficients C_{XX,-4} through C_{XX,+4} through the operation of multipliers 94. Outputs of multipliers 94 are added together at adders 95, which collectively provide the output for filter 68.

While FIGS. 1-4 specifically depict an embodiment of the present invention adapted to a complex signal path 10, this is not a requirement of the present invention. Those skilled in the art may adapt the teaching presented herein to a signal path for a real signal.

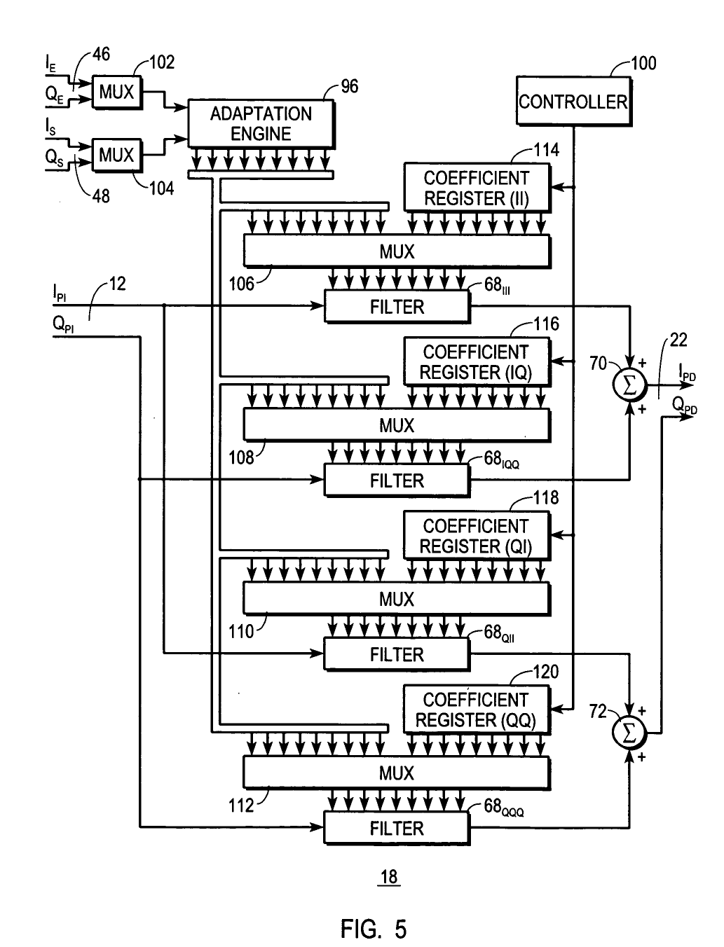

FIG. 5 shows a block diagram of an alternate embodiment of equalizer 18 that is particularly suited for a complex signal path 10 (FIG. 1). In this embodiment, path-input signal 12 drives four filters 68 whose outputs are combined in combining circuits 70 and 72 as discussed above in FIG. 2 to generate predistorted signal 22. But in this embodiment, a single adaptation engine 96 generates coefficients for only one of the four filters 68 at a time. And, adaptation engine 96 can be switched so that coefficients are generated for all of filters 68. The FIG. 5 embodiment may further reduce component complexity from the embodiment discussed above in connection with FIG. 2.

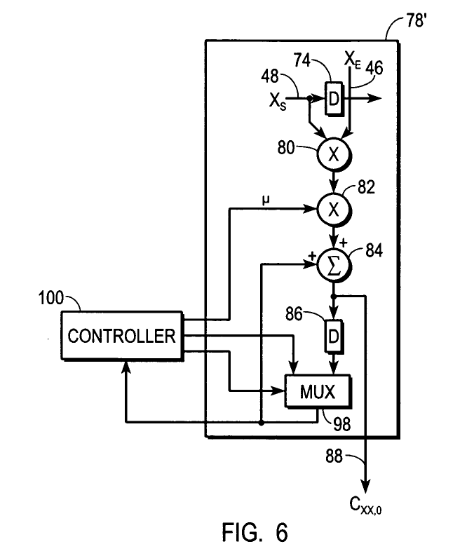

Except for a slight change discussed below in connection with FIG. 6, adaptation engine 96 may be configured substantially as discussed above in connection with FIG. 3 for a single coefficient generator section 66. In particular, FIG. 6 shows a block diagram of a tap slice 78′ of adaptation engine 96. Each tap slice in adaptation engine 96 may be configured as tap slice 78′. Tap slice 78′ is configured much like tap slice 78 from FIG. 3, except that a multiplexer (MUX) 98 is inserted so that the output from coefficient register 86 drives one of its data inputs and the data output of multiplexer 98 drives the second input of adder 84. FIG. 6. depicts a controller 100 driving another data input of multiplexer 98, the selection input of multiplexer 98, and providing the programmable constant μ to multiplier 82. Controller 100 is also configured to read the output from multiplexer 98.

By controlling programmable constant μ and the selection input of multiplexer 98, controller 100 can initialize coefficient register 86 to any desired value and read the contents of coefficient register 86. For normal operation, the selection input of multiplexer 98 is set to route the output of coefficient register 86 to the second input of adder 84. The process of reading the contents of coefficient register 86 may first lock adaptation engine 96 by setting programmable constant μ to zero, thereby causing the contents of coefficient register 86 to remain static. Then, controller 100 may input the value presented at the output of multiplexer 98. The process of initializing the contents of coefficient register 86 may first lock adaptation engine 96 so that an initial value to be written will not change as soon as it is written, control multiplexer 98 to route an output of controller 100 to the second input of adder 84, write the desired initial value, then set multiplexer 98 to again route the output of coefficient register 86 to the second input of adder 84. When controller 100 is ready to allow adaptation engine 96 (FIG. 5) to update its coefficients, programmable constant μ may be set to some desired value.

Referring back to FIG. 5, a multiplexer 102 receives in-phase component I_{E} and quadrature component Q_{E} Of error signal 46 and provides its output to the error signal input of adaptation engine 96. Likewise, a multiplexer 104 receives in-phase component I_{S} and quadrature component Q_{S} of subtraction signal 48 and provides its output to the subtraction signal input of adaptation engine 96. Coefficients C_{XX,-4} through C_{XX,+4} output from adaptation engine 96 are routed to first sets of inputs in each of multiplexers 106, 108, 110 and 112. Controller 100 provides data to coefficient registers 114, 116, 118 and 120 and controls selection inputs for each of multiplexers 106, 108, 110, and 112. Data outputs from coefficient registers 114, 116, 118 and 120 respectively couple to second sets of inputs of multiplexers 106, 108, 110 and 112.

In operation, adaptation engine 96 is configured to determine coefficients for one of filters 68 by appropriately controlling multiplexers 102, 104, 106, 108, 110, and 112. For example, coefficients are generated for filter 68_{III} by freezing adaptation engine 96 as discussed above. Desirably, the contents of coefficient registers 86 (FIG. 6) in adaptation engine 96 are read by controller 100 and transferred to the appropriate one of coefficient registers 114, 116, 118 and 120. Then, controller 100 desirably makes sure all multiplexers 106, 108, 110, and 112 are switched to route coefficients from coefficient registers 114, 116, 118, and 120 to the respective filters 68. Next, controller 100 may initialize coefficient registers 86 in adaptation engine 96 to a desired value. If an initial adaptation cycle is to begin, coefficient registers 86 are desirably initialized as discussed above. But if prior adaptation has taken place, the same coefficients currently being used in coefficient register 114 are desirably loaded into coefficient registers 86 for this filter 68_{III} example. Then multiplexer 106 is switched to route coefficients from adaptation engine 96 to filter 68_{III}, and adaptation engine 96 is unfrozen by supplying a non-zero value for μ (FIGS. 3 and 6).

After adaptation engine 96 has worked on converging coefficients for a while, the above-discussed process is repeated for another one of filters 68, and so on until coefficients have been updated for all filters 68. For each of filters 68, a different pair of correlation signals is selected at multiplexers 102 and 104 and routed to adaptation engine 96. Desirably, the process repeats many times for all of filters 68 within the time span of a few time constants of the convergence loop. If desired, over the course of the few time constants the programmable constant μ may be reduced. The larger values for μ at the beginning of the process speed convergence, and the smaller values for μ later on reduce jitter.

In summary, an improved equalized signal path having a predictive subtraction signal and a corresponding method are provided. In at least one embodiment of the present invention, one of the signals used in forming an error signal for the adaptation algorithm also operates as a predictive variable which the adaptation algorithm correlates with the error signal. And, in at least one embodiment of the present invention, a complex adaptive equalizer having four degrees of freedom is provided.

Although the preferred embodiments of the invention have been illustrated and described in detail, it will be readily apparent to those skilled in the art that various modifications may be made therein without departing from the spirit of the invention or from the scope of the appended claims. Such modifications and adaptations which are obvious to those skilled in the art are to be included within the scope of the present invention.

1. An equalized signal path into which a path-input signal flows and from which a path-output signal flows, said equalized signal path comprising:
a subtraction circuit configured to generate an error signal by combining first and second subtraction signals, wherein said first subtraction signal is a reference signal and said second subtraction signal is derived from said path-output signal;
a coefficient generator adapted to track correlation between said error signal and one of said subtraction signals; and
a multiplier circuit coupled to said coefficient generator and configured to scale said path-input signal in response to said correlation tracked by said coefficient generator.

2. An equalized signal path as claimed in claim 1 additionally comprising a distortion-introducing segment having an input coupled to said multiplier circuit and having an output which generates said path-output signal.

3. An equalized signal path as claimed in claim 2 additionally comprising a delay element having an input adapted to receive a signal derived from said path-input signal and having an output from which said reference signal is derived.

4. An equalized signal path as claimed in claim 3 wherein:
said multiplier circuit generates a predistorted signal;
said distortion-introducing segment applies a distortion-introduced delay to said predistorted signal; and
said delay element is configured to delay said path-input signal so that said first subtraction signal is substantially in temporal alignment with said second subtraction signal.

5. An equalized signal path as claimed in claim 1 wherein said path-input signal is a digital baseband communication signal and said path-output signal is an analog RF communication signal.

6. An equalized signal path as claimed in claim 1 wherein:
said coefficient generator comprises a tapped-delay line configured to progressively delay said one of said subtraction signals and is configured to generate separate coefficients in association with taps of said tapped-delay line; and
said multiplier circuit is included in a finite impulse response (FIR) filter that is responsive to said coefficients and to said path-input signal.

7. An equalized signal path as claimed in claim 1 wherein each of said path-input signal, said path-output signal, said first subtraction signal, said second subtraction signal, and said error signal is a complex signal having an in-phase (I) component and a quadrature (Q) component.

8. An equalized signal path as claimed in claim 7 wherein:
said coefficient generator comprises a tapped-delay line configured to progressively delay said one of said subtraction signals and is configured to generate four separate coefficients per tap of said tapped-delay line; and
said multiplier circuit is included in a finite impulse response (FIR) filter that is responsive to said coefficients and to said path-input signal.

9. An equalized signal path as claimed in claim 7 wherein said coefficient generator comprises:
an adaptation engine configured to selectively receive one pair of correlation signals at a time from the following four pairs of correlation signals:
said I component of said error signal and said I component of said one of said subtraction signals,
said I component of said error signal and said Q component of said one of said subtraction signals,
said Q component of said error signal and said I component of said one of said subtraction signals, and
said Q component of said error signal and said Q component of said one of said subtraction signals;
a first coefficient register coupled to said adaptation engine to record a coefficient derived from said I component of said error signal and said I component of said one of said subtraction signals;
a second coefficient register coupled to said adaptation engine to record a coefficient derived from said I component of said error signal and said Q component of said one of said subtraction signals;
a third coefficient register coupled to said adaptation engine to record a coefficient derived from said Q component of said error signal and said I component of said one of said subtraction signals; and
a fourth coefficient register coupled to said adaptation engine to record a coefficient derived from said Q component of said error signal and said Q component of said one of said subtraction signals.

10. An equalized signal path as claimed in claim 7 wherein said coefficient generator comprises:
a first coefficient register adapted to track correlation between said I component of said error signal and said I component of said one of said subtraction signals;
a second coefficient register adapted to track correlation between said I component of said error signal and said Q component of said one of said subtraction signals;
a third coefficient register adapted to track correlation between said Q component of said error signal and said I component of said one of said subtraction signals; and
a fourth coefficient register adapted to track correlation between said Q component of said error signal and said Q component of said one of said subtraction signals.

11. An equalized signal path as claimed in claim 10 wherein said multiplier circuit comprises
a first multiplier coupled to said first coefficient register and configured to scale said I component of said path-input signal;
a second multiplier coupled to said second coefficient register and configured to scale said Q component of said path-input signal;
a third multiplier coupled to said third coefficient register and configured to scale said I component of said path-input signal;
a fourth multiplier coupled to said fourth coefficient register and configured to scale said Q component of said path-input signal;
a first combination circuit coupled to said first and second multipliers; and
a second combination circuit coupled to said third and fourth multipliers.

12. An equalized signal path as claimed in claim 1 wherein said coefficient generator is adapted to track correlation between said error signal and said reference signal.

13. An equalized signal path as claimed in claim 1 wherein said reference signal is derived from said path-input signal without performing analog signal processing.

14. A method for equalizing a signal path into which a path-input signal flows and from which a path-output signal flows, said method comprising:
subtracting first and second subtraction signals to generate an error signal, wherein said first subtraction signal is a reference signal and said second subtraction signal is derived from said path-output signal;
correlating said error signal with one of said subtraction signals to generate a coefficient which tracks correlation between said error signal and said one of said subtraction signals; and
scaling said path-input signal in response to said coefficient.

15. A method as claimed in claim 14 wherein:
said scaling activity generates a predistorted signal; and
said method additionally comprises introducing distortion into said predistorted signal to generate said path-output signal.

16. A method as claimed in claim 15 additionally comprising delaying said path-input signal to derive said first subtraction signal from said path-input signal and to cause said first subtraction signal to be substantially in temporal alignment with said second subtraction signal.

17. A method as claimed in claim 14 wherein:
said path-input signal is a digital baseband communication signal;
said scaling activity generates a predistorted signal; and
said method additionally comprises converting said predistorted signal into an analog RF communication signal which serves as said path-output signal.

18. A method as claimed in claim 14 wherein:
said correlating activity comprises delaying said one of said subtraction signals in a tapped-delay line having a plurality of taps;
said correlating activity further comprises generating one coefficient per tap of said tapped-delay line; and
said scaling activity filters said path-input signal in a finite impulse response (FIR) filter that is responsive to said coefficients and to said path-input signal.

19. A method as claimed in claim 14 wherein each of said path-input signal, said path-output signal, said first subtraction signal, said second subtraction signal, and said error signal is a complex signal having an in-phase (I) component and a quadrature (Q) component.

20. A method as claimed in claim 19 wherein:
said correlating activity comprises delaying said one of said subtraction signals in a tapped-delay line having a plurality of taps;
said correlating activity further comprises generating four separate coefficients per tap of said tapped-delay line; and
said scaling activity filters said path-input signal in a finite impulse response (FIR) filter that is responsive to each of said four separate coefficients per tap of said tapped-delay line and to said path-input signal.

21. A method as claimed in claim 14 wherein:
said correlating activity correlates said error signal with said reference signal.

22. A method as claimed in claim 14 additionally comprising deriving said reference signal from said path-input signal without performing analog signal processing.

23. An equalized signal path into which a complex path-input signal flows and from which a complex path-output signal flows, said equalized signal path comprising:
a subtraction circuit configured to generate a complex error signal from a complex reference signal derived from said complex path-input signal without using analog signal processing and a complex subtraction signal derived from said complex path-output signal, wherein each of said complex signals has an I component and a Q component;
a first coefficient register adapted to track correlation between said I component of said complex error signal and said I component of said complex reference signal;
a second coefficient register adapted to track correlation between said I component of said complex error signal and said Q component of said complex reference signal;
a third coefficient register adapted to track correlation between said Q component of said complex error signal and said I component of said complex reference signal;
a fourth coefficient register adapted to track correlation between said Q component of said complex error signal and said Q component of said complex reference signal;
a first multiplier circuit coupled to said first coefficient register and configured to scale said I component of said complex path-input signal;
a second multiplier circuit coupled to said second coefficient register and configured to scale said Q component of said complex path-input signal;
a third multiplier circuit coupled to said third coefficient register and configured to scale said I component of said complex path-input signal;
a fourth multiplier circuit coupled to said fourth coefficient register and configured to scale said Q component of said complex path-input signal;
a first combination circuit coupled to said first and second multipliers to generate an I component for a complex equalized signal; and
a second combination circuit coupled to said third and fourth multipliers to generate a Q component for said complex equalized signal.

24. An equalized signal path as claimed in claim 23 wherein said complex path-input signal is a digital baseband communication signal and said complex path-output signal is an analog RF communication signal.

25. An equalized signal path as claimed in claim 23 additionally comprising:
an analog in-phase-distortion-introducing segment having an input coupled to said first combination circuit;
an analog quadrature-distortion-introducing segment having an input coupled to said second combination circuit; and
an analog combined-distortion-introducing segment having inputs coupled to said in-phase-distortion-introducing segment and to said quadrature-distortion-introducing segment and having an output configured to generate said complex path-output signal.

26. An equalized signal path as claimed in claim 23 additionally comprising:
a distortion-introducing segment having an input coupled to said first and second combination circuits and having an output which generates said complex path-output signal; and
a delay element having an input adapted to receive a signal derived from said complex path-input signal and having an output from which said complex reference signal is derived.

27. An equalized signal path as claimed in claim 26 wherein said delay element is configured to cause said complex reference signals to be substantially in temporal alignment with said complex subtraction signal.
